(19) United States
(12) Patent Application Publication
(10) Pub. No.: US 2022/0368352 A1
(43) Pub. Date: Nov. 17, 2022

(54) APPARATUS AND METHOD FOR PARALLEL REED-SOLOMON ENCODING

(71) Applicant: ELECTRONICS AND TELECOMMINICATIONS RESEARCH INSTITUTE, Daejeon (KR)

(72) Inventors: Hun Sik KANG, Daejeon (KR); Seung-Woo LEE, Daejeon (KR); Sun Hyok CHANG, Seoul (KR); In Ki HWANG, Sejong-si (KR)

(21) Appl. No.: 17/732,866

(22) Filed: Apr. 29, 2022

(30) Foreign Application Priority Data
May 7, 2021 (KR) 10-2021-0058919

(51) Int. Cl. H03M 13/15; H03M 13/00

(52) U.S. Cl. CPC H03M 13/1515; H03M 13/6502; H03M 13/1595

(57) ABSTRACT

Provided are an apparatus and method for parallel Reed-Solomon (RS) encoding. A parallel RS encoding apparatus includes a coefficient generator configured to calculate a parity symbol matrix and group coefficients of each row or each column of the parity symbol matrix to correspond to the number of parallel paths, a data delayer configured to delay a parallel input information symbol block including symbols of the number of parallel paths so that calculation of a parity symbol is processed in order, a parity symbol calculator configured to calculate, based on the grouped coefficients outputted from the coefficient generator and the parallel input information symbol block delayed by the data delayer, the parity symbol, and a parallel outputter configured to output a codeword generated based on the parity symbol outputted from the parity symbol calculator and the parallel input information symbol block delayed by the data delayer.

### CROSS-REFERENCE TO RELATED APPLICATION

This application claims the benefit of Korean Patent Application No. 10-2021-0058919 filed on May 7, 2021, in the Korean Intellectual Property Office, the entire disclosure of which is incorporated herein by reference for all purposes.

### BACKGROUND

### 1. Field of the Invention

One or more example embodiments relate to a parallel Reed-Solomon (RS) coding technology.

### 2. Description of Related Art

The importance and utilization of a technology for finding and correcting errors occurring in a process of information being transmitted by a system to deliver and recover information in addition to a communication system, are constantly being used. A technology that serves to detect and correct such errors is an error correction code technology. Among many error correction codes (ECC), an RS code, which is one of non-binary Bose, Chaudhuri and Hocquenghem (BCH) codes, has an advantage capable of recovering a burst error. In particular, the RS code is widely used for wireless communication, high-speed optical communication systems, and memory storage devices (disk, flash memory, and the like).

### SUMMARY

According to an aspect, there is provided a parallel RS encoding apparatus including a coefficient generator configured to calculate a parity symbol matrix and group coefficients of each row or each column of the parity symbol matrix to correspond to the number of parallel paths, a data delayer configured to delay a parallel input information symbol block including symbols of the number of parallel paths so that calculation of a parity symbol is processed in order, a parity symbol calculator configured to calculate, based on the grouped coefficients outputted from the coefficient generator and the parallel input information symbol block delayed by the data delayer, the parity symbol, and a parallel outputter configured to output a codeword generated based on the parity symbol outputted from the parity symbol calculator and the parallel input information symbol block delayed by the data delayer.

The coefficient generator may be configured to group, into one group, coefficients with an equal remainder obtained by dividing an index of each row or each column by the number of parallel paths.

The parallel outputter may include a parity parallel inserter configured to generate, based on a parallel input information symbol block having the longest delay time period among parallel input information symbol blocks delayed by the data delayer, and the parity symbol outputted from the parity symbol calculator, the codeword of the number of parallel paths.

The parallel outputter may further include a syndrome parallel outputter configured to perform, based on the parity symbol, calculation of a syndrome.

The parallel outputter may further include an operation mode selector configured to output, in response to an operation mode of a transmission mode or a reception mode, one of the codeword generated by the parity parallel inserter and the syndrome calculated by the syndrome parallel outputter.

The coefficient generator may be configured to calculate, using a generator polynomial, the parity symbol matrix and a systematic generator matrix, and calculate, from the systematic generator matrix, a parity check matrix and a coefficient matrix of the parity check matrix.

The coefficient generator may be configured to group coefficients of each row or each column of the coefficient matrix to correspond to the number of parallel paths.

The parity symbol calculator may include a coefficient transferor configured to transfer each coefficient of the grouped coefficients to a corresponding Galois field multiply and accumulator (GF-MAC), and the GF-MAC configured to perform a Galois field multiplication and accumulation operation between the each coefficient and a corresponding symbol among symbols included in the parallel input information symbol block.

The data delayer may include a first delay element configured to delay the parallel input information symbol block by a time period corresponding to one clock of an operation clock, and a second delay element configured to delay the parallel input information symbol block by a time period corresponding to a processing time period of the parity symbol calculator.

According to another aspect, there is provided a parallel RS encoding method including calculating a parity symbol matrix, and grouping coefficients of each row or each column of the parity symbol matrix to correspond to the number of parallel paths, delaying a parallel input information symbol block including symbols of the number of parallel paths so that calculation of the parity symbol is processed in order, calculating, based on the grouped coefficients and the delayed parallel input information symbol block, the parity symbol, and generating, based on the parity symbol and the delayed parallel input information symbol block, a codeword.

The grouping may include grouping, into one group, coefficients with an equal remainder obtained by dividing an index of each row or each column by the number of parallel paths.

The generating of the codeword may include generating, based on a parallel input information symbol block having the longest delay time period among delayed parallel input information symbol blocks and the parity symbol, the codeword of the number of parallel paths.

The parallel RS encoding method may further include performing, based on the parity symbol, calculation of a syndrome.

The parallel RS encoding method may further include selecting one of an operation mode of a transmission mode or a reception mode, outputting the codeword when the transmission mode is selected, and outputting the syndrome when the reception mode is selected.

The grouping may include calculating, using a generator polynomial, the parity symbol matrix and a systematic generator matrix, and calculating, from the systematic generator matrix, a parity check matrix and a coefficient matrix of the parity check matrix.

The grouping may further include grouping coefficients of each row or each column of the coefficient matrix to correspond to the number of parallel paths.

The calculating of the parity symbol may include transferring each coefficient of the grouped coefficients to a corresponding GF-MAC, and performing a Galois field multiplication and accumulation operation between the each coefficient and a corresponding symbol among symbols included in the parallel input information symbol block.

The delaying of the parallel input information symbol block may include delaying the parallel input information symbol block by a time period corresponding to one clock of an operation clock, and delaying the parallel input information symbol block by a time period corresponding to a processing time period of the calculating of the parity symbol.

Additional aspects of example embodiments will be set forth in part in the description which follows and, in part, will be apparent from the description, or may be learned by practice of the disclosure.

According to example embodiments, it is possible to provide an apparatus for calculating a parity in parallel by generating, using the fact that a parity symbol is obtained through a product of an input information symbol and a generator matrix, coefficients of the generation matrix according to parallel path processing, and transferring the coefficients, thereby speeding up encoding processing.

According to example embodiments, a parity symbol and a syndrome may be calculated using one structure, thereby reducing complexity of an encoding apparatus.

According to example embodiments, even when RS codes with different error correction rates are used, only matrix coefficients of the RS codes with different error correction rates may be transferred, thereby performing symbol encoding and syndrome calculation without a change in configuration.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 is a block diagram illustrating a configuration of a parallel RS encoding apparatus according to an example embodiment;

FIG. 2 is a diagram illustrating a configuration of a parallel input information symbol block according to an example embodiment;

FIG. 3 is a flowchart illustrating an operation of a coefficient generator according to an example embodiment;

FIG. 4 is a diagram illustrating grouped coefficients of a systematic generator matrix according to an example embodiment;

FIG. 5 is a block diagram illustrating a configuration of a parity symbol calculator according to an example embodiment;

FIG. 6 is a block diagram illustrating a configuration of a parallel outputter according to an example embodiment;

FIG. 7 is a diagram illustrating a meaning of a syndrome;

FIG. 8 is a diagram illustrating a process in which a codeword is calculated by a parity parallel inserter according to an example embodiment;

FIGS. 9A and 9B are diagrams illustrating a process in which a syndrome is calculated by a syndrome parallel outputter according to an example embodiment; and

FIG. 10 is a flowchart illustrating a parallel RS encoding method according to an example embodiment.

### DETAILED DESCRIPTION OF THE INVENTION

Hereinafter, example embodiments will be described in detail with reference to the accompanying drawings. Various modifications may be made to the example embodiments and the scope of the disclosure is not limited to the example embodiments. Here, the example embodiments are not construed as limited to the disclosure and should be understood to include all changes, equivalents, and replacements within the idea and the technical scope of the disclosure.

The terminology used herein is for the purpose of describing particular example embodiments only and is not to be limiting of the example embodiments. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, components or a combination thereof, but do not preclude the presence or addition of one or more other features, integers, steps, operations, elements, components, and/or groups thereof.

Although terms of “first,” “second,” and the like are used to explain various components, the components are not limited to such terms. These terms are used only to distinguish one component from another component. For example, a first component may be referred to as a second component, or similarly, the second component may be referred to as the first component within the scope of the present disclosure.

Unless otherwise defined herein, all terms used herein including technical or scientific terms have the same meanings as those generally understood by one of ordinary skill in the art. Terms defined in dictionaries generally used should be construed to have meanings matching contextual meanings in the related art and are not to be construed as an ideal or excessively formal meaning unless otherwise defined herein.

When describing the example embodiments with reference to the accompanying drawings, like reference numerals refer to like components and a repeated description related thereto will be omitted. When describing the example embodiments, detailed description of well-known related structures or functions will be omitted when it is deemed that such description will cause ambiguous interpretation of the example embodiments.

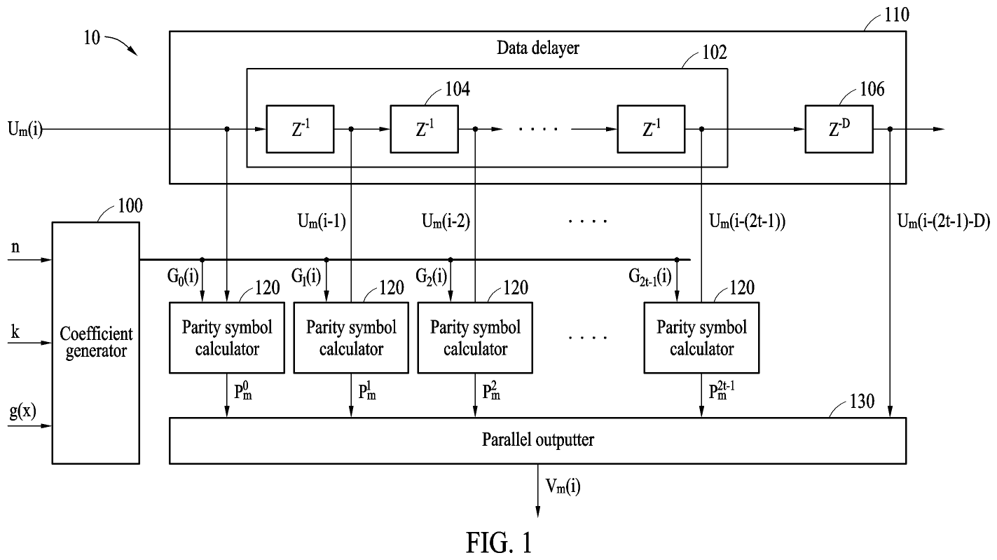

FIG. 1 is a block diagram illustrating a configuration of a parallel RS encoding apparatus 10 according to an example embodiment.

An RS encoding method is being used as an error correction technology for transferring data with integrity due to an increase in communication and storage media with higher data processing speed. When RS encoding and decoding are serially processed, in a recent high-speed communication system that requires transmission at a speed of several Giga bits per second (Gbps) to several tens of Gbps, an operation clock of the encoding apparatus needs to be operated at a speed of several GHz to several tens of GHz, and thus there is difficulty in processing.

The parallel RS encoding apparatus 10 according to an example embodiment may overcome a limitation on high-speed processing in encoding of an RS code and calculation of a syndrome, and may encode a symbol and calculate the syndrome without a constraint on the number of parallel paths, using a systematic generator matrix.

The RS error correction code may be processed on a block-by-block basis. Through an RS encoding process, n−k (n is a constant) coded additional symbols (for example, parity symbols) may be added to inputted k (k is a constant) information symbols to output one codeword. Such a relationship may be represented and defined by RS(n,k,t). Here, t (t is a constant), which represents the number of symbols for which error correction is possible, may be represented by t=(n−k)/2. For example, in KP4 forward error correction (FEC) used for optical communication, RS(544,514,15) may be defined. The number of input information symbols k may be 514, the number of symbols in a codeword n may be 544, and the number of symbols for which error correction is possible t may be 15. RS(544,514,15) may represent that error correction is possible for 15 symbols among k=514 symbols entering an input block. A symbol may follow an operation rule defined by a Galois field (GF) on a basis in which an operation in an RS code is performed. When one symbol is represented by 10 bits, a size of the symbol becomes GF(2¹⁰)=GF(1024), and this GF may have 1024 symbols. For encoding and decoding of the RS code, a generator polynomial g(x) may be required. The generator polynomial g(x) of RS(n,k,t) may be represented by Equation 1.

$$g ( x ) = ( x + α ) ( x + {α}^{2} ) … ( x + {α}^{2 t} ) = {g}_{0} + {g}_{1} x + {g}_{2} {x}^{2} + … + {g}_{2 t - 1} {x}^{2 t - 1} \qquad [ Equation 1 ]$$

Here, α may represent a primitive root in a corresponding GF.

Referring to FIG. 1, the parallel RS encoding apparatus 10 according to an example embodiment may include a coefficient generator 100, a data delayer 110, a parity symbol calculator 120, and a parallel outputter 130.

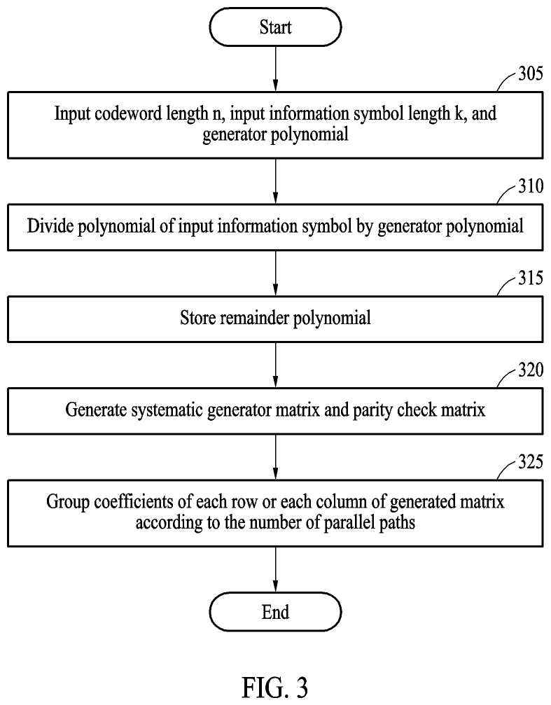

The coefficient generator 100 of the parallel RS encoding apparatus 10 according to an example embodiment may calculate a parity symbol matrix G_{A} and a systematic generator matrix Gₛ, using, as inputs, an input information symbol length k and an output codeword length n of the RS code, and the generator polynomial g(x) of the RS code. The coefficient generator 100 may group each coefficient of the calculated parity symbol matrix G_{A} to correspond to the number of parallel paths for parallel processing. Each of the grouped coefficients G₀(i), G₁(i), . . . , G₂ₜ₋ᵢ(i) may be inputted into the corresponding parity symbol calculator 120. An operation of the coefficient generator 100 is described in detail below with reference to FIG. 3.

In an example embodiment, the coefficient generator 100 may generate a systematic generator matrix. Thus, in an encoding process, an input information symbol may be outputted as it is, and only a parity symbol related to the input information symbol may be calculated, thereby reducing complexity of a decoding process.

In an example embodiment, the coefficient generator 100 may generate a parity check matrix from the systematic generator matrix, and the parity check matrix may be used to calculate a syndrome in a process of decoding a reception symbol.

The data delayer 110 of the parallel RS encoding apparatus 10 according to an example embodiment may delay a parallel input information symbol block inputted into the parallel RS encoding apparatus 10 so that parity symbol calculation is performed in order (pipeline). The data delayer 110 may include a plurality of delay elements. In an example embodiment, the data delayer 110 may include delay elements 102 that enables pipeline processing by the parity symbol calculator 120, and a delay element 106 that allows a time period corresponding to a processing time period of the parity symbol calculator 120 to be delayed. In an example embodiment, a time period delayed by a delay element 104 may be a time period corresponding to one clock of the operation clock.

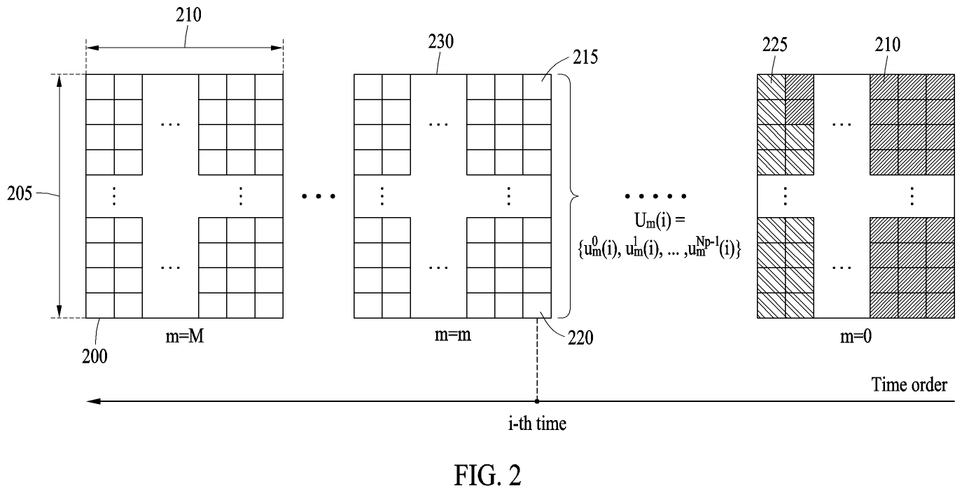

In an example embodiment, a parallel input information symbol block including input information symbols may be inputted into the data delayer 110. The input information symbol and the parallel input information symbol block are described in detail below with reference to FIG. 2. The data delayer 110 may output the delayed parallel input information symbol block Uₘ(i), Uₘ(i−1), . . . , Uₘ(i−(2t−1)) by allowing parallel input information symbol blocks to be delayed by the delay element 104. Each of the delayed parallel input information symbol block Uₘ(i), Uₘ(i−1), . . . , Uₘ(i−(2t−1)) may be inputted into the corresponding parity symbol calculator 120.

The data delayer 110 may output a delayed parallel input information symbol block Uₘ(i−(2t−1)−D) by allowing a parallel input information symbol block to be delayed by the delay elements 102 and the delay element 106. The delayed parallel input information symbol block Uₘ(i−(2t−1)−D) may be inputted into the parallel outputter 130. In an example embodiment, a time period D delayed by the delay element 106 may correspond to the processing time period of the parity symbol calculator 120. However, time periods delayed by the delay element 104 and the delay element 106 are not limited thereto, and a time period suitable for a usage mode may be set as a delay time period.

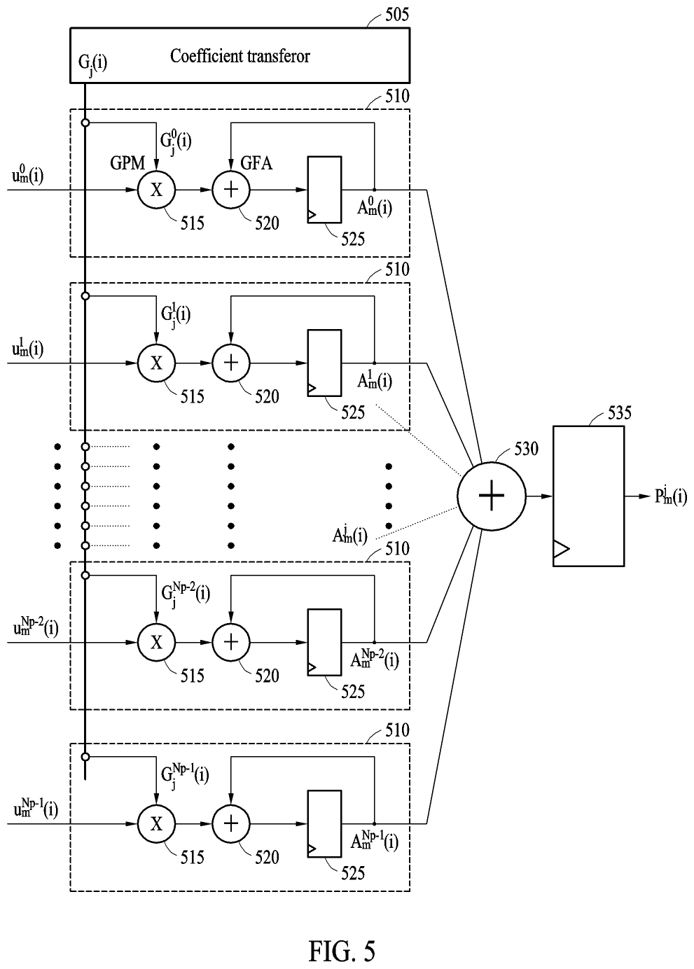

The parity symbol calculator 120 of the parallel RS encoding apparatus 10 according to an example embodiment may calculate the parity symbol, based on the grouped coefficients outputted from the coefficient generator 100 and the parallel input information symbol block delayed by the data delayer 110. The parallel RS encoding apparatus 10 according an example embodiment may include a plurality of parity symbol calculators 120. In an example embodiment, the parallel RS encoding apparatus 10 may include 2t−1 parity symbol calculators 120. Each parity symbol calculator 120 may calculate each parity symbol pₘ⁰, pₘ¹, . . . , pₘ^{2t-1} corresponding to each parity symbol calculator 120 as illustrated in FIG. 1, using, as inputs, a corresponding parallel input information symbol block among the parallel input information symbol blocks Uₘ(i), Uₘ(i−1), . . . , Uₘ(i−(2t−1)) outputted from the data delayer 110 and a corresponding coefficient among the coefficients G₀(i), G₁(i), . . . , G₂ₜ₋₁(i) outputted from the coefficient generator 100. The parity symbol calculator 120 is described in detail below with reference to FIG. 5.

The parallel outputer 130 of the parallel RS encoding apparatus 10 according to an example embodiment may output a codeword, based on the parity symbol outputted from the parity symbol calculator 120 in response to an operation mode and the parallel input information symbol block delayed by the data delayer 110, or may calculate and output a syndrome, based on the parity symbol.

The parallel outputter 130 according to an example embodiment may parallelize and output the codeword or syndrome to correspond to the number of parallel paths.

In an example embodiment, the parallel RS encoding apparatus 10 may not use a generator matrix generated using coefficients of a generator polynomial, but may configure a parity symbol matrix and a systematic generator matrix to use the matrices for encoding and decoding, and may group and process coefficients of the parity symbol matrix to correspond to the number of parallel paths, thereby performing encoding and decoding without limitation on the number of parallel paths. The parallel RS encoding apparatus 10 may speed up processing of encoding and decoding by processing in parallel, and may lower an operating speed of an encoding and decoding apparatus required by a system that transmits data at a speed of several Gbps to several tens of Gbps.

FIG. 2 is a diagram illustrating a configuration of a parallel input information symbol block 230 according to an example embodiment.

FIG. 2 illustrates parallel input information symbol blocks 200 inputted into the parallel RS encoding apparatus 10 in chronological order.

An RS code may be outputted by adding n−k coded parity symbols to k information symbols 210. When processing with Np (Np is a constant) parallel paths 205, an input information symbol U={u₀, u₁, u₂, . . . , uₖ₋₁} including k information symbols 210 may form the parallel input information symbol block 200 with a size (Np×ceil(n/Np)), as illustrated in FIG. 2. Here, a ceil(x) function may represent an integer greater than x. The parallel input information symbol block 200 may include ceil(n/Np) 210 parallel input information symbol blocks 230 including Np 205 symbols. In FIG. 2, an i (i is a constant)-th time and an m (m is a constant)-th parallel input information symbol block 230 may be represented by Uₘ(i). The parallel input information symbol block Uₘ(i) 230 may include Np 205 symbols {uₘ⁰(i), uₘ¹(i), . . . , uₘ^{Np-1}(i)}. For example, uₘ⁰(i) 215 may represent a symbol on a zeroth parallel path at an i-th time and an m-th block, and uₘ^{Np-1}(i) 220 may represent a symbol on a sixteenth parallel path at the i-th time and the m-th block.

(n−k) parity symbols may need to be added to the k information symbols 210 in an encoding process, and thus (Np×ceil(n/Np)−k) symbols may be added as a dummy symbol 225. In an example embodiment, the dummy symbol 225 may be filled with symbol “0” or another symbol. For example, when parallel processing is performed with the number of parallel paths 205 Np=16 according to RS(544,514,15) using KP4 FEC used for optical communication, a length of the parallel input information symbol block 200 may be ceil (544/16)=34. A length of the added dummy symbol 225 may be (544−514)=30, and thirty symbols may be divided and allocated to a parallel input information symbol block having i=33 and a parallel input information symbol block having i=34.

The RS code may belong to a cyclic error correction code, and thus a parity may be generated using a generator matrix Gₙₛ. The generator matrix Gₙₛ may be generated with a size of (k×n), and may be represented by Equation 2.

$${G}_{ns} = [ ( \begin{matrix}{g}_{0} & {g}_{1} & {g}_{2} & \cdot & \cdot & \cdot & {g}_{n - k} & 0 & 0 & \cdot & \cdot & 0 \\ 0 & {g}_{0} & {g}_{1} & {g}_{2} & \cdot & \cdot & \cdot & {g}_{n - k} & 0 & \cdot & \cdot & 0 \\ 0 & 0 & {g}_{0} & {g}_{1} & {g}_{2} & \cdot & \cdot & \cdot & {g}_{n - k} & \cdot & \cdot & 0 \\ & ⋮ & & & & & ⋮ & & & & ⋮ & \\ 0 & 0 & 0 & & & \cdot & \cdot & 0 & & \cdot & \cdot & 0 \\ 0 & 0 & 0 & & & \cdot & \cdot & 0 & & \cdot & \cdot & 0 \\ 0 & 0 & 0 & & & \cdot & \cdot & {g}_{0} & & \cdot & \cdot & {g}_{n - k}\end{matrix} ) ] \qquad [ Equation 2 ]$$

When an coded output code is generated, the coded output code v may be calculated as v=UGₙₛ using a generator matrix Gₙₛ. The generator matrix Gₙₛ may be non-systematic. Thus, when the coded output code is generated using the generator matrix Gₙₛ, a value of an input information symbol U may be encoded, and thus there is a short-coming in that a decoding process becomes complicated. In an example embodiment, the systematic generator matrix Gₛ may be be derived so that the input information symbol U is outputted as it is and only a parity symbol related to the input information symbol U is calculated. The systematic generator matrix Gₛ may be generated as shown in Equation 3.

Gₛ=(P_{k×n-k}|I_{k×k}) [Equation 3]

Here, I_{k×k} may be an identity matrix having k rows and k columns, and P_{k×n-k} may be a parity symbol matrix having k rows and n−k columns. When the parity symbol is calculated using the systematic generator matrix Gₛ, a parity value related to the input information symbol U may be calculated without encoding of the input information symbol U.

The parallel RS encoding apparatus 10 according to an example embodiment may calculate a parity symbol matrix G_{A} and the systematic generator matrix Gₛ, group coefficients of the parity symbol matrix G_{A} according to the number of parallel paths for parallel processing, and process calculation of a parity symbol and a syndrome in parallel, thereby processing at high speed.

The parallel RS encoding apparatus 10 according to an example embodiment may calculate both the parity symbol and the syndrome using one parallel processing structure. In optical communication such as half-duplex communication, transmission and reception may not be performed simultaneously, and thus the parallel RS encoding apparatus 10 may output a parity symbol during transmission and a syndrome during reception without a configuration, thereby reducing complexity of the apparatus.

Even when RS codes having different error correction rates are used instead of using only one specific RS code according to a communication environment, the parallel RS encoding apparatus 10 according to an example embodiment may perform calculation of the parity symbol and the syndrome without an implementation for generating the RS codes.

FIG. 3 is a flowchart illustrating an operation of the coefficient generator 100 according to an example embodiment.

The coefficient generator 100 according to an example embodiment may calculate a parity symbol matrix and a systematic generator matrix, and group each coefficient of the parity symbol matrix to correspond to the number of parallel paths. The coefficient generator 100 according to an example embodiment may generate a parity check matrix and a coefficient matrix of the parity check matrix from the calculated systematic generator matrix, and group coefficients of each row or each column of the coefficient matrix to correspond to the number of parallel paths.

In operation 305, the coefficient generator 100 may receive an input information symbol length k and an output codeword length n of of an RS code, and a generator polynomial g(x) of the RS code. In operation 310, the coefficient generator 100 may calculate a remainder polynomial bₗ(x) required for parity symbol calculation by dividing x^{n-k+l} by the generator polynomial g(x). The coefficient generator 100 may calculate the remainder polynomial bₗ(x) according to l by dividing x^{n-k+l} by the generator polynomial g(x), while increasing a value of l from 0 to k−1, so as to obtain coefficients of the systematic generator matrix.

The parity symbol may be obtained by calculating a remainder obtained by dividing a polynomial x^{n-k}U(x) of an input information symbol U (for example, the input information symbol U in FIG. 2) by the generator polynomial g(x). The remainder obtained by dividing the polynomial x^{n-k}U(x) by the generator polynomial g(x) may be represented by Equation 4.

$$b ( x ) = mod ( \frac{{x}^{n - k} \cdot ( {u}_{0} + {u}_{1} x + {u}_{2} {x}^{2} + … + {u}_{k - 1} {x}^{k - 1} )}{g ( x )} ) = mod ( {\sum }_{l = 0}^{k - 1} \frac{{u}_{l} \cdot {x}^{n - k + l}}{g ( x )} ) = [ {u}_{0} {u}_{1} … {u}_{k - 1} ] [ \begin{matrix}mod ( \frac{{x}^{n - k}}{g ( x )} ) \\ ⋮ \\ mod ( \frac{{x}^{n - 1}}{g ( x )} )\end{matrix} ] \qquad [ Equation 4 ]$$

Here, a mod( ) function may represent a function that finds a remainder. b(x) may represent a polynomial of a remainder obtained by dividing the polynomial x^{n-k}U(x) by the generator polynomial g(x), k may represent a length of an input information symbol, n may represent a length of an output codeword, g(x) may represent a generator polynomial, and a polynomial x^{n-k}. (u₀+u₁x+u₂x²+ . . . +uₖ₋₁x^{k-1}) may represent the polynomial x^{n-k}U(x) of the input information symbol. As shown in Equation 4, the polynomial b(x) may be represented by a product of values obtained by dividing x^{n-k+l}|_{l=0,1, . . . ,k-1} by the generator polynomial g(x) and the input information symbol U. When a value obtained by dividing x^{n-k+l}|_{l=0,1, . . . ,k-1} by the generator polynomial g(x) may be represented by the remainder polynomial bₗ(x) according to l, a relationship shown in Equation 5 may be satisfied.

bₗ(x)=b_{l,0}+b_{l,1}x+b_{l,2}x²+ . . . b_{l,n-k-1}x^{n-k-1} [Equation 5]

Here, bₗ(x) may represent a polynomial obtained by dividing x^{n-k+l}|_{l=0,1, . . . ,k-1} according to l by the generator polynomial g(x), and b_{l,p}|_{p=0,1, . . . ,n-k-1} may be coefficients of bₗ(x).

In operation 315, the coefficient generator 100 may store the generated remainder polynomial bₗ(x).

In operation 320, the coefficient generator 100 may calculate, based on the remainder polynomial bₗ(x), the systematic generator matrix. When a parity symbol matrix P_{k×(n-k)} is represented by a matrix G_{A} based on the remainder polynomial bₗ(x), the parity symbol matrix P_{k×(n-k)} may be represented by Equation 6.

$${P}_{k \times ( n - k )} = {G}_{A} = [ \begin{matrix}{b}_{0 , 0} & {b}_{0 , 1} & {b}_{0 , j} & & {b}_{0 , n - k - 1} \\ {b}_{1 , 0} & {b}_{1 , 1} & {b}_{1 , j} & … & {b}_{1 , n - k - 1} \\ {b}_{2 , 0} & {b}_{2 , 1} & {b}_{2 , j} & & {b}_{2 , n - k - 1} \\ & ⋮ & & ⋱ & ⋮ \\ {b}_{k - 1 , 0} & {b}_{k - 1 , 1} & {b}_{k - 1 , j} & … & {b}_{k - 1 , n - k - 1}\end{matrix} ] \qquad [ Equation 6 ]$$

Here, P_{k×(n-k)} and G_{A} may be a parity symbol matrix, and each coefficient of P_{k×(n-k)} and G_{A} may be a coefficient of a remainder polynomial bₗ(x)|_{l=0,1, . . . ,k-1}. The coefficient generator 100 may represent a systematic generator matrix Gₛ, as shown in Equation 7.

Gₛ=(G_{A}|I_{k×k}) [Equation 7]

Here, Gₛ may be a systematic generator matrix, G_{A} may be a parity symbol matrix, and I_{k×k} may be an identity matrix having k rows and k columns.

In an example embodiment, the coefficient generator 100 may generate a parity check matrix Hₛ used to determine whether there is an error in a symbol received by a receiving end by calculating a transposed matrix of the matrix Gₛ. The parity check matrix Hₛ may be represented by Equation 8.

Hₛ=(G_{A}|I_{k×k})^{T}=(I_{k×k}|H_{A}) [Equation 8]

Here, Hₛ may be a parity check matrix, G_{A} may be a parity symbol matrix, I_{k×k} may be an identity matrix having k rows and k columns, and H_{A} may be a coefficient matrix.

The coefficient matrix H_{A} of the parity check matrix Hₛ may be used to calculate a syndrome S for determining whether an error occurs during transmission of a coded symbol.

The coefficient generator 100 according to an example embodiment may calculate a systematic generator matrix during transmission and calculate a parity check matrix during reception, without a structural change. The coefficient generator 100 according to an example embodiment may calculate the systematic generator matrix during transmission, and calculate the parity check matrix during reception, thereby reducing complexity of an encoding and decoding apparatus in a half-duplex communication system. The parity symbol may be calculated as U·G_{A} or G_{A}·U^{T}. The syndrome S may be calculated as H_{A}·r or r·H_{A}^{T} based on the received symbol r.

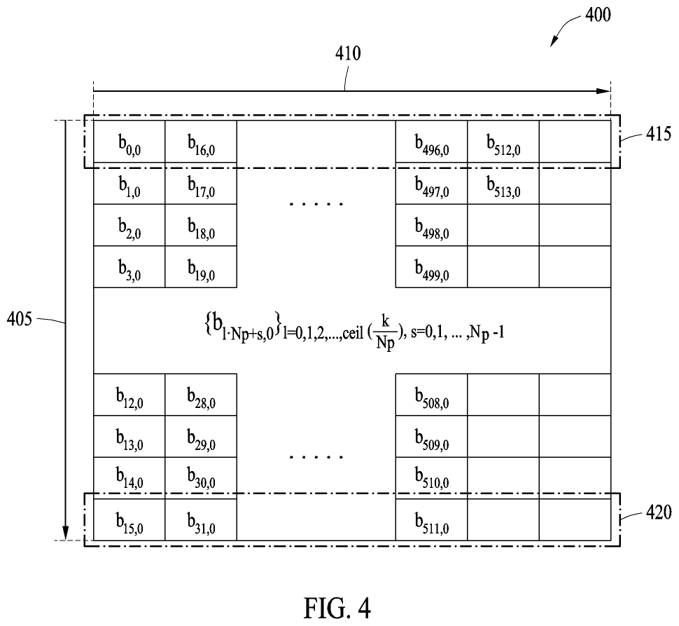

In operation 325, the coefficient generator 100 may group coefficients of each row or each column of the systematic generator matrix according to the number of parallel paths (for example, the number of parallel paths Np in FIG. 2). The grouping of operation 325 is described in detail below with reference to FIG. 4. The coefficient generator 100 may output the grouped coefficients to the parity symbol calculator 120.

FIG. 4 is a diagram illustrating grouped coefficients of a systematic generator matrix according to an example embodiment.

The coefficient generator 100 according to an example embodiment may calculate a systematic generator matrix, and group coefficients of each row or each column of the systematic generator matrix according to the number of parallel paths (for example, the number of parallel paths Np in FIG. 2).

FIG. 4 illustrates a row 400 of the grouped systematic generator matrix according to an example embodiment. For example, the coefficient illustrated in FIG. 4 may be a grouping of a first row of the systematic generator matrix.

In an example embodiment, the coefficient generator 100 may group, in the form of Gⱼ^{s}, a matrix coefficient b_{i,j} with an equal remainder value s 405 obtained by dividing an index l 410 of a row by the number of parallel paths Np. When the matrix G_{A} is represented by a collection of column vectors, the matrix G_{A} may be represented by G_{A}={G₀,G₁, . . . Gⱼ, . . . , Gₙ₋ₖ₋₁}. Each column vector including a collection of matrix coefficients b_{i,j} having the equal remainder value s 405 obtained by dividing l 410 by the number of parallel paths Np may be represented by Gⱼ={Gⱼ⁰,Gⱼ¹, . . . Gⱼ^{s}, . . . ,Gⱼ^{Np-1}}. For example, a first column vector of G₀ in an RS(544,514,15) code with Np=16 may be classified as G₀={G₀⁰,G₀¹, . . . G₀^{s}, . . . ,G₀¹⁶⁻¹} according to a value of s 405. For example, G₀⁰ 415 may be classified as

$${G}_{0}^{0} = {\{ {b}_{l \cdot {N}_{p} + s , 0 )} \}}_{l = 0 , 1 , 2 , … , ceil ( \frac{k}{{N}_{p}} ) , s = 0} ,$$

and G₀¹⁵ 420 may be classified as

$${G}_{0}^{15} = {\{ {b}_{l \cdot {N}_{p} + s , 0} \}}_{l = 0 , 1 , 2 , … , ceil ( \frac{k}{{N}_{p}} ) , s = 15} .$$

Coefficients required for parity calculation may be grouped to correspond to the number of parallel paths Np, and thus a partial dot product between a parallel input information symbol block Uₘ(i)={uₘ⁰(i),uₘ¹(i), . . . ,uₘ^{Np-1}(i)} and the grouped coefficients may be performed by the parity symbol calculator 120.

FIG. 5 is a block diagram illustrating a configuration of the parity symbol calculator 120 according to an example embodiment.

Referring to FIG. 5, the parity symbol calculator 120 of the parallel RS encoding apparatus 10 according to an example embodiment may include a matrix coefficient transferor 505, at least one GF-MAC 510, a Galois field adder (GFA) 530, and a storage element 535.

The matrix coefficient transferor 505 of the parity symbol calculator 120 according to an example embodiment may receive a grouped coefficient Gⱼ^{s}|_{s=0,1,2, . . . ,N}_{ₚ}₋₁ corresponding to a j-th parity symbol calculator 120 among grouped coefficients generated by the coefficient generator 100, and transfer each coefficient of the grouped coefficients to the corresponding GF-MAC 510. A corresponding parallel input information symbol block among parallel input information symbol blocks delayed by the data delayer 110 may be inputted into the parity symbol calculator 120. A symbol corresponding each GF-MAC 510 among symbols uₘ^{s}(i)|_{s=0,1,2, . . . ,N}_{ₚ}₋₁ included in the inputted parallel input information symbol block, and a coefficient transferred from the coefficient transferor 505 may be further inputted into each GF-MAC 510.

In an example embodiment, each GF-MAC 510 may include a Galois field multiplier (GFM) 515, a GFA 520, and a storage element 525. A coefficient and symbol inputted into the GF-MAC 510 may be multiplied by the GFM 515, and may be accumulated through a Galois field accumulator including the GFA 520 and the storage element 525.

The parity symbol calculator 120 according to an example embodiment may calculate a parity symbol by adding outputs Aₘ^{s}(i)|_{s=0,1,2, . . . ,N}_{ₚ}₋₁ of the GF-MAC 510, and store the parity symbol in the storage device 535. The parity symbol calculator 120 may output the stored parity symbol Pₘ^{j}(i).

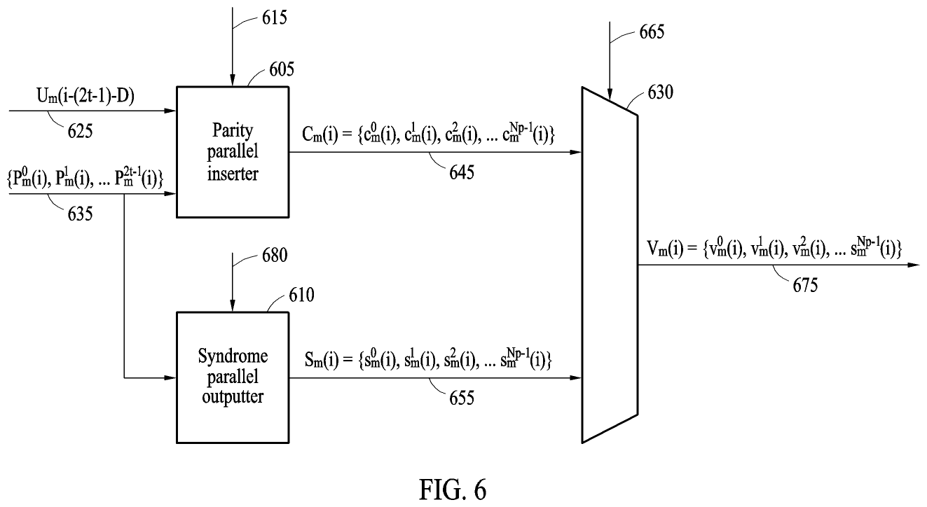

FIG. 6 is a block diagram illustrating a configuration of the parallel outputter 130 according to an example embodiment.

Referring to FIG. 6, the parallel outputter 130 according to an example embodiment may include a parity parallel inserter 605 and a syndrome parallel outputter 610.

The parity parallel inserter 605 according to an example embodiment may receive a parity symbol {Pₘ⁰(i),Pₘ¹(i), . . . ,Pₘ^{2t-1}(i)} 635 outputted from the parity symbol calculator 120 and a parallel input information symbol block Uₘ(i−(2t−1)−D) 625 outputted from the data delayer 110. The parity parallel inserter 605 may insert, based on a timing control signal 615, the parity symbol 635 into the parallel input information symbol block Uₘ(i−(2t−1)−D) 625, and generate a codeword Cₘ(i)={Cₘ⁰(i),Cₘ¹(i), . . . ,Cₘ^{Np-1}(i)} 645 to correspond to the number of parallel paths Np. The parity parallel inserter 605 may output the codeword Cₘ(i) as the output signal Vₘ(i) 675.

The syndrome parallel outputter 610 according an example embodiment may generate, based on the parity symbol {pₘ⁰(i),Pₘ¹(i), . . . ,Pₘ^{2t-1}(i)} 635, a syndrome Sₘ(i)={Sₘ⁰(i),sₘ¹(i), . . . ,sₘ^{Np-1}(i)} 655 corresponding to the number of parallel paths Np according to the timing control signal 680. The parity parallel inserter 605 may output the syndrome Sₘ(i) 655 as the output signal Vₘ(i) 675.

The parallel outputter 130 according to an example embodiment may further include an operation mode selector 630. The operation mode selector 630 may output, based on an operation mode selection signal 665, the codeword Cₘ(i) 645 outputted from the parity parallel inserter 605 or the syndrome 655 outputted from the syndrome parallel outputter 610. In an example embodiment, an operation mode may include a transmission mode for encoding a symbol to transmit a signal, and a reception mode for generating the syndrome Sₘ(i) 655 to receive a signal. The operation mode selector may output the codeword Cₘ(i) 645 when the transmission mode is selected, and may select the syndrome Sₘ(i) 655 when the reception mode is selected.

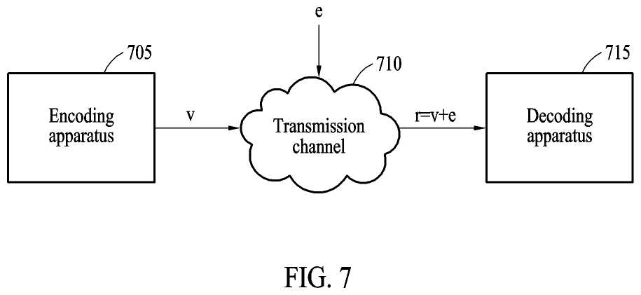

FIG. 7 is a diagram illustrating a meaning of a syndrome.

FIG. 7 illustrates a communication process in which an output signal of an encoding apparatus 705 is transferred to a decoding apparatus 715 through a transmission channel 710. The output signal of the encoding apparatus 705 may include noise or an error caused by an effect of the transmission channel 710 while passing through the transmission channel 710. A reception signal received by the decoding apparatus 715 may include not only the output signal of the encoding apparatus 705 but also an error.

The decoding apparatus 715 may detect whether an error is included in the reception signal so as to fully understand information included in the signal outputted from the encoding apparatus 705, and may perform restoration when there is an error. The decoding apparatus 715 may use a syndrome to detect whether an error is included in the reception signal. The syndrome may represent a calculation result capable of detecting whether an error occurs during transmission of an encoded signal.

In an example embodiment, the encoding apparatus 705 may generate an encoded output signal using the systematic generator matrix Gₛ of Equation 7. The decoding apparatus 715 may calculate the syndrome using the parity check matrix of Equation 8. The syndrome may be calculated as shown in Equation 9.

s=r·Hₛ^{T} [Equation 9]

Here, s may be a syndrome, Hₛ may be a parity check matrix, and r may be a reception signal of the decoding apparatus 715.

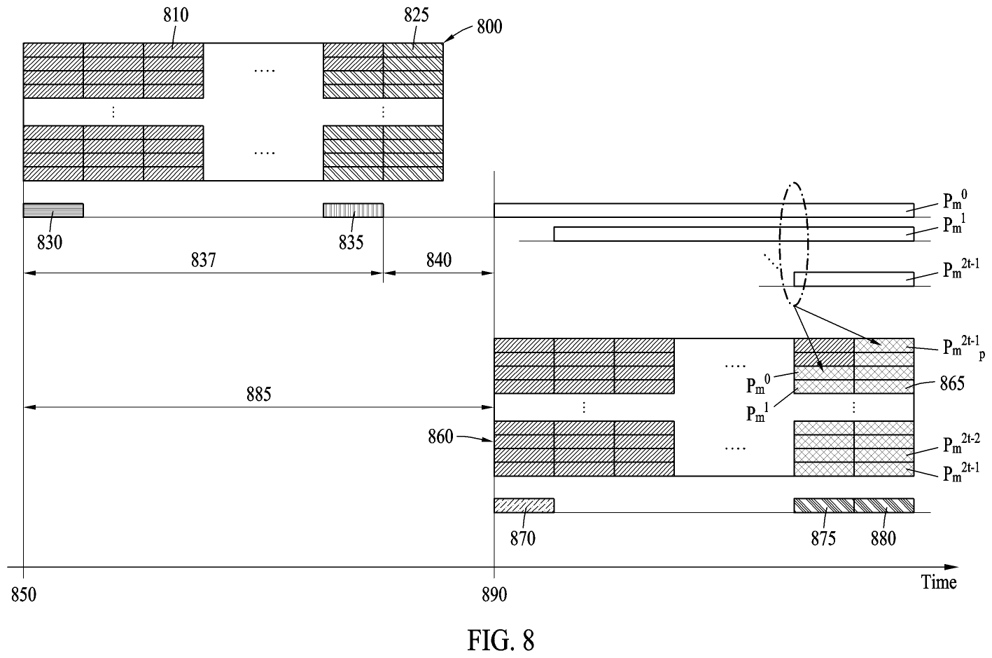

FIG. 8 is a diagram illustrating a process in which a codeword is calculated by a parity parallel inserter according to an example embodiment.

FIG. 8 illustrates a time-dependent process in which a parallel input information symbol block Uₘ(i) 800 inputted into the parallel RS encoding apparatus 10 and a parallel input information symbol block 800 are processed to generate an output by the parity symbol calculator 120, and a codeword Cₘ(i) 860 is generated based on a delayed parallel input information symbol block and a parity symbol outputted from the parity symbol calculator 120.

In an example embodiment, the parity parallel inserter 615 may determine a position of a dummy symbol 825 in a delayed parallel input information symbol block Uₘ(i−(2t−1)−D), that is, a position to be filled with parity symbols, and may insert parity symbols 865 calculated from the parity symbol calculator 120.

At a time 850, the parallel input information symbol block 800 including an information symbol 810 and a dummy symbol 825 may be inputted into the parallel RS encoding apparatus 10. The parallel input information symbol block 800 may be delayed by a delay time period 837 through the delay elements 102 of the data delayer 110, may be delayed by a delay time period 840 through the delay element 106, and may be delayed by a total delay time period 885.

From a time 890, a parity symbol 865 may be calculated from the parity symbol calculator 120, and may be outputted in order. The parity parallel inserter 615 may insert, based on timing control signals 870, 875, and 880, the calculated parity symbols 865 into the delayed parallel input information symbol block, and may generate a codeword 860.

The timing control signals 870, 875, and 880 may be signals generated by delaying a start signal 830 and an end signal 835 respectively representing a start and an end of the parallel input information symbol block 800 by the total delay time period 885. The timing control signals 870, 875, and 880 may include a codeword start signal 870 generated by delaying the start signal 830 by the total delay time period 885 and parallel insertion control signals 875 and 880. The parallel insertion control signals 875 and 880 may be generated to be maintained for two symbol sections.

The parity parallel inserter 615 may insert, into the delayed parallel input information symbol block, the parity symbols 865 up to Pₘ⁰,Pₘ¹, . . . ,Pₘ^{2t-1-N}^{ₚ}₋₁ for a section of the parallel insertion control signal 875, and may insert, into the delayed parallel input information symbol block, the parity symbols 865 up to Pₘ^{2t-1-N}^{ₚ}, . . . ,Pₘ^{2t-1} for a section of the parallel insertion control signal 880, thereby generating the codeword 860.

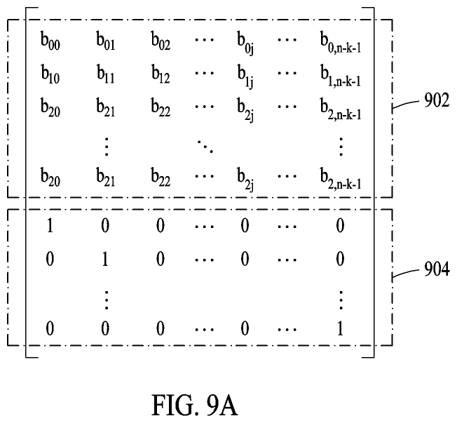

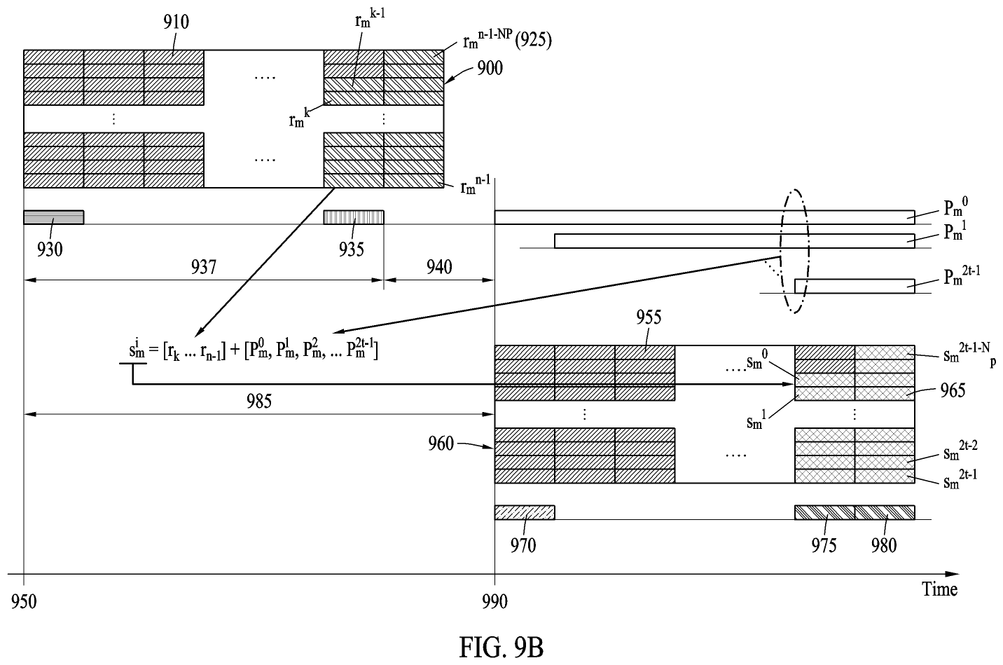

FIGS. 9A and 9B are diagrams illustrating a process in which a syndrome is calculated by a syndrome parallel outputter according to an example embodiment.

FIG. 9A illustrates a matrix Hₛ^{T}. A portion 902 may correspond to a matrix G_{A}, and a portion 904 may correspond to an identity matrix with a size of n−k×n−k. As described above, the syndrome may be calculated as shown in Equation 9. A reception signal r may be represented by Equation 10.

r=[r₀,r₁, . . . ,rₖ₋₁|rₖ, . . . ,rₙ₋₁] [Equation 10]

Here, r may be a reception signal, and r₀, r₁, . . . , rₖ₋₁, and rₖ, . . . , rₙ₋₁ may represent coefficients of a matrix of the reception signal. When there is no error during transmission, [r₀,r₁, . . . ,rₖ₋₁] may correspond to an information symbol, and [rₖ, . . . ,rₙ₋₁] may correspond to a parity symbol [p₀, . . . ,p₂ₜ₋₁].

Based on FIG. 9A, Equation 9, and Equation 10, when there is no error during transmission, a syndrome s may be calculated as shown in Equation 11.

$$s = [ {u}_{0} , {u}_{1} , … , {u}_{k - 1} ] {G}_{A} + {[ {p}_{0} , … , {p}_{2 t - 1} ]}^{T} = {[ {p}_{0} , … , {p}_{2 t - 1} ]}^{T} + {[ {p}_{0} , … , {p}_{2 t - 1} ]}^{T} = {[ 0 … 0 ]}^{T} \qquad [ Equation 11 ]$$

Here, s may be a syndrome, [u₀,u₁, . . . ,uₖ₋₁] may be an information symbol corresponding to [r₀,r₁, . . . ,rₖ₋₁] of the reception signal, and [p₀, . . . ,p₂ₜ₋₁] may be a parity symbol corresponding to [rₖ, . . . ,rₙ₋₁] of the reception signal. When there is no error during transmission, a sum of equal values in a GF may be zero. Therefore, when an error occurs during transmission, all values of the syndrome s may not become 0, thereby verifying detection of the error.

FIG. 9B illustrates a time-dependent process in which a parallel input information symbol block rₘ(i) 900 including reception symbols 910 and a parallel input information symbol block 900 are processed to generate an output by the parity symbol calculator 120, and syndrome symbols 965 are calculated based on a delayed parallel input information symbol block and a parity symbol outputted from the parity symbol calculator 120.

In an example embodiment, the syndrome parallel outputter 610 may calculate the syndrome symbols 965 from the reception signal, and output a syndrome sₘ(i) 960.

At a time 950, the parallel input information symbol block 900 including an information symbol 910 and a parity symbol 925 may be inputted into the parallel RS encoding apparatus 10. The parallel input information symbol block 900 may be delayed by a delay time period 2t−1 937 through the delay elements 102 of the data delayer 110, may be delayed by a delay time period D 940 through the delay element 106, and may be delayed by a total delay time period 2t−1+D 985.

From a time 990, parity symbols based on the parallel input information symbol block 900 may be calculated from the parity symbol calculator 120, and may be outputted in order. The syndrome parallel outputter 610 may calculate the syndrome symbols 965, based on the calculated parity symbols and the parity symbols 925 included in the parallel input information symbol block 900. The syndrome parallel outputter 610 may generate a syndrome 960 by inserting, into the delayed parallel input information symbol block, the syndrome symbols 965 calculated based on the timing control signals 970, 975, and 980.

The timing control signals 970, 975, and 980 may be signals generated by delaying a start signal 930 and an end signal 935 respectively representing a start and an end of the parallel input information symbol block 900 by the total delay time period 985. The timing control signals 970, 975, and 980 may include a syndrome start signal 970 generated by delaying the start signal 930 by the total delay time period 985, and parallel insertion control signals 975 and 980. The parallel insertion control signals 975 and 980 may be generated to be maintained for two symbol sections.

The syndrome parallel outputter 610 may insert, into the delayed parallel input information symbol block, the syndrome symbols 965 up to sₘ⁰,sₘ¹, . . . ,sₘ^{2t-1-N}^{ₚ}⁻¹ for a section of the parallel insertion control signal 975, and may insert, into the delayed parallel input information symbol block, the syndrome symbols 965 up to sₘ^{2t-1-N}^{ₚ}, . . . ,sₘ^{2t-1} for a section of the parallel insertion control signal 980.

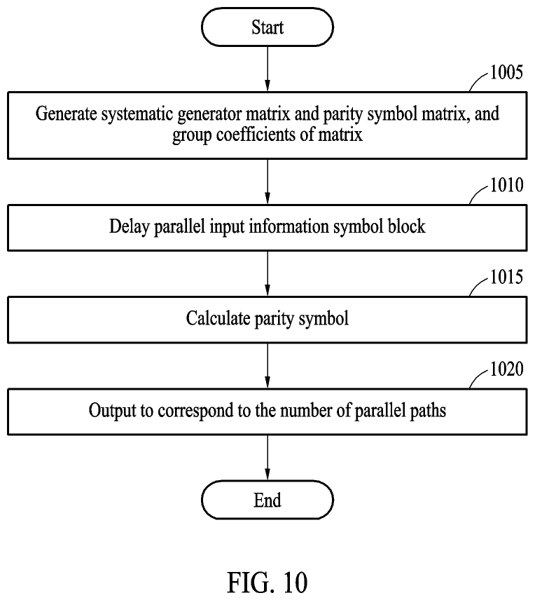

FIG. 10 is a flowchart illustrating a parallel RS encoding method according to an example embodiment.

FIG. 10 illustrates a flowchart illustrating a parallel RS encoding method performed by the parallel RS encoding apparatus 10 according to an example embodiment.

In operation 1005, the parallel RS encoding apparatus 10 may calculate a systematic generator matrix Gₛ using, as inputs, an input information symbol length k and an output codeword length n of an RS code, and a generator polynomial g(x) of the RS code. The parallel RS encoding apparatus 10 may group each coefficient of the systematic generator matrix Gₛ to correspond to the number of parallel paths for parallel processing so as to calculate a parity symbol. The grouping of the coefficients is described in detail above with reference to FIGS. 3 and 4, and thus a repeated description will be omitted.

In operation 1010, the parallel RS encoding apparatus 10 may delay a parallel input information symbol block inputted into the parallel RS encoding apparatus 10 so that parity symbol calculation is performed in order (pipeline). Each delayed parallel input information symbol block may correspond to the parity symbol calculator 120 or the parallel outputter 130.

In operation 1015, the parallel RS encoding apparatus 10 may calculate a parity symbol, based on the coefficients grouped in operation 1005 and the parallel input information symbol block delayed in operation 1010. In an example embodiment, the parallel RS encoding apparatus 10 may transfer each coefficient of the grouped coefficients to a corresponding GF-MAC among the GF-MACs 510 included in the parity symbol calculator 120 of the parallel RS encoding apparatus 10.

A symbol corresponding to each GF-MAC among symbols included in the parallel input information symbol block may be further inputted into each GF-MAC 510. Each GF-MAC 510 may perform a Galois field multiplication accumulation operation, and outputs of the GF-MACs may be summed to calculate the parity symbol. The parity symbol may be stored in the storage element 535 of the parity symbol calculator 120, and the stored parity symbol may be outputted to the parallel outputter 130.

In operation 1020, the parallel RS encoding apparatus 10 may generate a codeword corresponding to the number of parallel paths by inserting the parity symbol calculated in operation 1015 into a parallel input information symbol block (for example, Uₘ(i−(2t−1)−D) in FIG. 1) having the longest delay time period among the parallel input information symbol blocks delayed in operation 1010.

The parallel RS encoding apparatus 10 may calculate, based on the parity symbol calculated in operation 1015, a syndrome corresponding to the number of parallel paths.

A parallel RS encoding and decoding method may further include selecting an operation mode. In response to an operation selected in the selecting of the operation mode, the parallel RS encoding apparatus 10 may output the generated codeword or syndrome.

The operation mode may include a transmission mode for encoding a symbol to transmit a signal and a reception mode for generating a syndrome to receive a signal, and the parallel RS encoding apparatus 10 may output the codeword when the reception mode is selected, and may output the syndrome when the reception mode is selected. The components described in the example embodiments may be implemented by hardware components including, for example, at least one digital signal processor (DSP), a processor, a controller, an application-specific integrated circuit (ASIC), a programmable logic element, such as a field programmable gate array (FPGA), other electronic devices, or combinations thereof. At least some of the functions or the processes described in the example embodiments may be implemented by software, and the software may be recorded on a recording medium. The components, the functions, and the processes described in the example embodiments may be implemented by a combination of hardware and software.

The example embodiments described herein may be implemented using hardware components, software components, or a combination thereof. A processing device may be implemented using one or more general-purpose or special purpose computers, such as, for example, a processor, a controller and an arithmetic logic unit, a digital signal processor, a microcomputer, a field programmable array, a programmable logic unit, a microprocessor or any other device capable of responding to and executing instructions in a defined manner. The processing device may run an operating system (OS) and one or more software applications that run on the OS. The processing device also may access, store, manipulate, process, and create data in response to execution of the software. For purpose of simplicity, the description of a processing device is used as singular; however, one skilled in the art will appreciated that a processing device may include multiple processing elements and multiple types of processing elements. For example, a processing device may include multiple processors or a processor and a controller. In addition, different processing configurations are possible, such as parallel processors.

The software may include a computer program, a piece of code, an instruction, or some combination thereof, to independently or collectively instruct or configure the processing device to operate as desired. Software and data may be embodied permanently or temporarily in any type of machine, component, physical or virtual equipment, computer storage medium or device, or in a propagated signal wave capable of providing instructions or data to or being interpreted by the processing device. The software also may be distributed over network coupled computer systems so that the software is stored and executed in a distributed fashion. The software and data may be stored by one or more non-transitory computer readable recording mediums.

The method according to the above-described example embodiments may be recorded in non-transitory computer-readable media including program instructions to implement various operations which may be performed by a computer. The media may also include, alone or in combination with the program instructions, data files, data structures, and the like. The program instructions recorded on the media may be those specially designed and constructed for the purposes of the example embodiments, or they may be of the well-known kind and available to those having skill in the computer software arts. Examples of non-transitory computer-readable media include magnetic media such as hard disks, floppy disks, and magnetic tape; optical media such as CD ROM discs and DVDs; magneto-optical media such as optical discs; and hardware devices that are specially configured to store and perform program instructions, such as read-only memory (ROM), random access memory (RAM), flash memory, and the like. Examples of program instructions include both machine code, such as code produced by a compiler, and files containing higher level code that may be executed by the computer using an interpreter.

The described hardware devices may be configured to act as one or more software modules in order to perform the operations of the above-described example embodiments, or vice versa.

While this disclosure includes example embodiments, it will be apparent to one of ordinary skill in the art that various changes in form and details may be made in these example embodiments without departing from the spirit and scope of the claims and their equivalents. The example embodiments described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner and/or replaced or supplemented by other components or their equivalents.

Therefore, the scope of the disclosure is defined not by the detailed description, but by the claims and their equivalents, and all variations within the scope of the claims and their equivalents are to be construed as being included in the disclosure.

What is claimed is:

1. An apparatus for processing Reed-Solomon (RS) encoding in parallel, the apparatus comprising:
a coefficient generator configured to calculate a parity symbol matrix and group coefficients of each row or each column of the parity symbol matrix to correspond to the number of parallel paths;
a data delayer configured to delay a parallel input information symbol block including symbols of the number of parallel paths so that calculation of a parity symbol is processed in order;
a parity symbol calculator configured to calculate, based on the grouped coefficients outputted from the coefficient generator and the parallel input information symbol block delayed by the data delayer, the parity symbol; and
a parallel outputter configured to output a codeword generated based on the parity symbol outputted from the parity symbol calculator and the parallel input information symbol block delayed by the data delayer.

2. The apparatus of claim 1, wherein the coefficient generator is configured to group, into one group, coefficients with an equal remainder obtained by dividing an index of each row or each column by the number of parallel paths.

3. The apparatus of claim 1, wherein the parallel outputter comprises a parity parallel inserter configured to generate, based on a parallel input information symbol block having the longest delay time period among parallel input information symbol blocks delayed by the data delayer, and the parity symbol outputted from the parity symbol calculator, the codeword of the number of parallel paths.

4. The apparatus of claim 3, wherein the parallel outputter further comprises a syndrome parallel outputter configured to perform, based on the parity symbol, calculation of a syndrome.

5. The apparatus of claim 4, wherein the parallel outputter further comprises an operation mode selector configured to output, in response to an operation mode of a transmission mode or a reception mode, one of the codeword generated by the parity parallel inserter and the syndrome calculated by the syndrome parallel outputter.

6. The apparatus of claim 1, the coefficient generator is configured to calculate, using a generator polynomial, the parity symbol matrix and a systematic generator matrix, and calculate, from the systematic generator matrix, a parity check matrix and a coefficient matrix of the parity check matrix.

7. The apparatus of claim 6, the coefficient generator is configured to group coefficients of each row or each column of the coefficient matrix to correspond to the number of parallel paths.

8. The apparatus of claim 1, wherein the parity symbol calculator comprises:
a coefficient transferor configured to transfer each coefficient of the grouped coefficients to a corresponding Galois field multiply and accumulator (GF-MAC); and
the GF-MAC configured to perform a Galois field multiplication and accumulation operation between the each coefficient and a corresponding symbol among symbols included in the parallel input information symbol block.

9. The apparatus of claim 1, wherein the data delayer comprises:
a first delay element configured to delay the parallel input information symbol block by a time period corresponding to one clock of an operation clock; and
a second delay element configured to delay the parallel input information symbol block by a time period corresponding to a processing time period of the parity symbol calculator.

10. A method of processing Reed-Solomon (RS) encoding in parallel, the method comprising:
calculating a parity symbol matrix, and grouping coefficients of each row or each column of the parity symbol matrix to correspond to the number of parallel paths;
delaying a parallel input information symbol block including symbols of the number of parallel paths so that calculation of the parity symbol is processed in order;
calculating, based on the grouped coefficients and the delayed parallel input information symbol block, the parity symbol; and
generating, based on the parity symbol and the delayed parallel input information symbol block, a codeword.

11. The method of claim 10, wherein the grouping comprises grouping, into one group, coefficients with an equal remainder obtained by dividing an index of each row or each column by the number of parallel paths.

12. The method of claim 10, wherein the generating of the codeword comprises generating, based on a parallel input information symbol block having the longest delay time period among delayed parallel input information symbol blocks and the parity symbol, the codeword of the number of parallel paths.

13. The method of claim 12, further comprising:
performing, based on the parity symbol, calculation of a syndrome.

14. The method of claim 13, further comprising:
selecting one of an operation mode of a transmission mode or a reception mode;
outputting the codeword when the transmission mode is selected; and
outputting the syndrome when the reception mode is selected.

15. The method of claim 10, wherein the grouping comprises:
calculating, using a generator polynomial, the parity symbol matrix and a systematic generator matrix; and
calculating, from the systematic generator matrix, a parity check matrix and a coefficient matrix of the parity check matrix.

16. The method of claim 15, wherein the grouping further comprises grouping coefficients of each row or each column of the coefficient matrix to correspond to the number of parallel paths.

17. The method of claim 10, wherein the calculating of the parity symbol comprises:
transferring each coefficient of the grouped coefficients to a corresponding Galois field multiply and accumulator (GF-MAC); and
performing a Galois field multiplication and accumulation operation between the each coefficient and a corresponding symbol among symbols included in the parallel input information symbol block.

18. The method of claim 10, wherein the delaying of the parallel input information symbol block comprises:
delaying the parallel input information symbol block by a time period corresponding to one clock of an operation clock; and
delaying the parallel input information symbol block by a time period corresponding to a processing time period of the calculating of the parity symbol.
